(19) United States
(12) Patent Application Publication
(10) Pub. No.: US 2024/0213159 A1
(43) Pub. Date: Jun. 27, 2024

(54) GRAPHENE-CAPPED COPPER IN DUAL DAMASCENE INTERCONNECT

(71) Applicant: Lam Research Corporation, Fremont, CA (US)

(72) Inventors: Asish Parbatani, Albany, NY (US); Bart J. van Schravendijk, Palo Alto, CA (US); Bhadri N. Varadarajan, Beaverton, OR (US); Ieva Narkeviciute, Portland, OR (US); Easwar Srinivasan, Portland, OR (US); Kashish Sharma, Tigard, OR (US); Randolph Knarr, Voorheesville, NY (US); Stefan Schmitz, Malta, NY (US); Vinayak Ramanan, Portland, OR (US)

(21) Appl. No.: 18/291,200

(22) PCT Filed: Jul. 19, 2022
(86) PCT No.: PCT/US2022/073906

§ 371 Date: Jan. 22, 2024

Related U.S. Application Data
(60) Provisional application No. 63/203,480, filed on Jul. 23, 2021.

(51) Int. Cl. H01L 23/532; C23C 16/04; C23C 16/26; C23C 16/455; C23C 16/56; H01L 21/768

(52) U.S. Cl. CPC H01L 23/53276; C23C 16/04; C23C 16/26; C23C 16/45525; C23C 16/56; H01L 21/7685; H01L 23/53238

(57) ABSTRACT

A method for selectively depositing graphene on a metal surface in a back-end-of-line substrate is provided. The method comprises providing the substrate comprising a first dielectric layer and a copper interconnect in the first dielectric layer, the copper interconnect having an exposed metal surface, wherein the exposed metal surface comprises copper, and selectively deposing a carbon layer on the exposed metal surface.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### STATEMENT ON JOINT RESEARCH AGREEMENT

At least some of the subject matter disclosed has been made by or on behalf of a party to a joint development agreement with effective date of 2016 Sep. 27, as amended. The parties to the Joint Development Agreement are Lam Research Corporation and International Business Machines Corporation.

### BACKGROUND

Graphene is an allotrope of carbon in which the atoms are arrayed in a single atom sheet in a regular hexagonal pattern. Graphene has attracted interest in many fields and industries because of its high electrical conductivity, high thermal conductivity, good mechanical strength and toughness, optical transparency, and high electron mobility, among other favorable properties. Interest in graphene is growing in the semiconductor industry.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method for forming a dual damascene structure on a semiconductor substrate, the method including: providing the semiconductor substrate including a first dielectric layer and a copper interconnect in the first dielectric layer, the copper interconnect having an exposed metal surface, whereby the exposed metal surface includes copper; and selectively depositing a carbon layer on the exposed metal surface.

In various embodiments, selectively depositing the carbon layer on the exposed metal surface includes: flowing one or more hydrocarbon precursors into a reaction chamber and towards the semiconductor substrate; generating, from a hydrogen source gas, radicals of hydrogen in a remote plasma source; and introducing the radicals of hydrogen into the reaction chamber and towards the semiconductor substrate, whereby the radicals of hydrogen react with the one or more hydrocarbon precursors to deposit the carbon layer on the exposed metal surface.

In various embodiments, the carbon layer includes carbon bonded in a hexagonal lattice.

In various embodiments, the carbon layer is selectively deposited at a temperature of less than about 400° C.

In various embodiments, the method also includes treating the carbon layer with a non-direct plasma. For example, in some embodiments, the non-direct plasma includes radicals selected from the group consisting of OH* radicals, O* radicals, H* radicals, radicals of ammonia, radicals of nitrogen, and combinations thereof.

In various embodiments, the method also includes, after selectively depositing the carbon layer on the exposed metal surface, depositing a hermetic barrier over the carbon layer. In various embodiments, the method also includes depositing a second dielectric material over the hermetic barrier. For example, in some embodiments, the carbon layer inhibits deposition of the second dielectric material on the carbon layer when the second dielectric material is deposited on the first dielectric layer. In some embodiments, the second dielectric material includes a metal oxide. For example, in some embodiments, the metal oxide includes aluminum oxide, hafnium oxide, zirconium oxide, yttrium oxide, zinc oxide, titanium oxide, or combinations thereof.

In various embodiments, the carbon layer is deposited to a thickness of less than about 3 monolayers.

In various embodiments, the first dielectric layer includes a low-k dielectric material.

Another aspect involves a semiconductor device including: a first dielectric layer having a via; a liner layer conformally lining sidewalls of the via; a copper material formed over the liner layer in the via, the copper material having an exposed cobalt-free copper surface planar with a planar surface of the first dielectric layer; a carbon cap selectively formed directly on the exposed cobalt-free copper surface relative to the first dielectric layer and treated by exposure to plasma; a hermetic barrier over the carbon cap; and a second dielectric layer formed over the hermetic barrier.

In various embodiments, the second dielectric layer includes a metal oxide. For example, in some embodiments, the metal oxide includes aluminum oxide, hafnium oxide, zirconium oxide, yttrium oxide, zinc oxide, titanium oxide, or combinations thereof.

In various embodiments, the carbon cap has a thickness of less than about 3 monolayers.

In various embodiments, the carbon cap includes sp2 hybridized carbon.

These and other aspects are described further below with reference to the drawings.

### BRIEF DESCRIPTION OF THE DRAWINGS

FIG. 1 illustrates a cross-sectional schematic of an example substrate having a metal surface with graphene deposited thereon according to some implementations.

FIG. 2 shows a cross-sectional schematic illustration of an example semiconductor device having a selective graphene film and a dielectric layer in a dual damascene structure according to some implementations.

FIG. 3 shows a dual damascene copper interconnect scheme with graphene cap formed directly on copper.

FIGS. 4A-4E show cross-sectional schematics of a process of selective deposition using graphene according to some implementations.

FIG. 5 is a process flow diagram of an example method of depositing graphene on a metal surface of a substrate according to some implementations.

FIG. 6 is a process flow diagram of an example method of depositing graphene on a metal surface of a substrate according to some implementations.

FIG. 7 illustrates a schematic diagram of an example plasma processing apparatus with a remote plasma source according to some implementations.

FIG. 8 illustrates a schematic diagram of an example process chamber for performing disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

While the scaling limit of copper interconnects drives development of alternative metals, extension of Cu damascene schemes is the preference in the logic chip industry. The challenge for Cu extension is the reduction of line resistance (Line R) without losing manufacturability and reliability.

There is a growing interest in forming carbon layers and/or carbon caps in semiconductor applications. Carbon layers and/or carbon caps include carbon-containing layers, elemental carbon, graphene, and pure carbon materials. Carbon layers and/or carbon caps may include graphene, or may have at least about 10% graphene by weight, or at least about 20% graphene by weight, or at least about 30% graphene by weight, or at least about 40% graphene by weight, or at least about 50% graphene by weight, or at least about 60% graphene by weight, or at least about 70% graphene by weight, or at least about 80% graphene by weight, or at least about 90% graphene by weight. “Graphene” as used herein includes carbon-based material that may have a mixture of sp2 and sp3 hybridized carbon. “Graphene” includes carbon having only sp2 bonds. “Graphene” includes carbon having at least about 50% sp2 bonds, or at least about 60% sp2 bonds, or at least about 70% sp2 bonds, or at least about 80% sp2 bonds, or at least about 90% sp2 bonds, or about 100% sp2 bonds. “Graphene” includes a monolayer of carbon atoms arranged in a hexagonal lattice. “Graphene” includes one or more monolayers of carbon atoms bonded to carbon atoms, including bilayers of carbon bonded to carbon, trilayers of carbon bonded to carbon, and thicker variations thereof. “Graphene” includes a monolayer of elemental carbon. It will be understood that while some embodiments of graphene may have mostly sp2 hybridized carbons, in some embodiments, a mixture of sp2 and sp3 hybridized carbons may be present. Graphene may include mostly carbon, with little to no dopants or other atoms therein. In some embodiments, graphene may have a lattice structure. In some embodiments, graphene is 100% carbon. In some embodiments, graphene is dopant-free. In some embodiments, graphene is hydrogen-free.

However, there are many challenges associated with the production of graphene in sufficient quantities and under suitable conditions for semiconductor integration. Many production methods suffer from low surface coverage because of the difficulty of growing graphene with minimal defects. Thus, scalability to produce large-area graphene films presents a particular problem, especially large-area graphene films on semiconductor wafers. Graphene films may be grown by thermal chemical vapor deposition (CVD). Thermal CVD methods may be used for synthesis of large-area, high-quality graphene. Thermal CVD of graphene may be performed at elevated temperatures, which may not necessarily be compatible with certain semiconductor applications. Graphene film deposition generally involves a temperature higher than 400° C. which is too high for BEOL integration processes. Some graphene deposition processes are described in J. Jiang, Jae H. Chu, and K. Banerjee, “CMOS-Compatible Doped-Multilayer-Graphene Interconnects for Next-Generation VLSI,” in IEEE IEDM2018-799 which is herein incorporated by reference in its entirety. BEOL may refer to “back end of line” processing which may refer to process operations performed after metal is deposited on a wafer. Graphene deposition is typically done by thermal CVD, at elevated temperatures (800° C.-1000° C.), which is not compatible with semiconductor technology. Such high temperatures may not be compatible with advanced semiconductor devices and current BEOL materials. For example excess diffusion of dopants, metals and/or structural damage may occur. BEOL interconnects have metal and low k dielectric lines and graphene deposition on metal lines can reduce the line resistance, but to integrate such embodiments, deposition of graphene is selectively deposited on metal relative to low-k dielectric material.

The thermal CVD process involves at least two steps: activation of gaseous precursors and chemical reaction to form a stable, solid film on a suitable substrate. In thermal CVD, activation of gaseous precursors can occur by thermal decomposition. At elevated temperatures, hydrocarbon precursors thermally decompose and adsorb onto a substrate surface. Hydrocarbon radicals are chemically reactive and may interact with the substrate surface. The substrate surface may be a metal surface that acts as a catalyst for nucleation and growth of graphene. Without being limited by any theory, the catalytic metal surface may dehydrogenate the hydrocarbon radicals so that carbon atoms may bond with other carbon atoms, thereby promoting nucleation and growth of graphene. Various transition metals such as copper have been recognized as catalysts for nucleation and growth of graphene. Graphene capping on copper wires may be one of the potential solutions to reduce line resistance and improve electromigration and/or time-dependent dielectric breakdown (EMfDDB) reliability, which is described in R. Mehta, S. Chugh, and Z. Chen's “Enhanced Electrical and Thermal Conduction in Graphene-Encapsulated Copper Nanowires,” Nano Lett. 2015, 15, 3, 2024-2030; L. Li and H.-S. Philip Wong, “Integrating Graphene into Future Generations of Interconnect Wires” 2018 IEEE International Electron Devices Meeting (IEDM); and L. Li, Z Thu, T. Wang, J. A. Currivan-Incorvia, A. Yoon, and H.-S. Philip Wong, “BEOL Compatible Graphene/Cu with Improved Electromigration Lifetime for Future Interconnects,” 2015 IEEE International Electron Devices Meeting (IEDM), which are herein incorporated by reference in their entireties.

Activation of hydrocarbon species and graphene growth can depend on factors such as temperature and the metal surface on which graphene is grown. In addition, graphene growth can depend on carbon solubility on the metal surface. If the metal has high carbon solubility, carbon more easily dissolves in the metal and tends to precipitate on the metal surface. This generally leads to less uniform graphene layers and more microstructural defects owing to multiple nucleation sites and an unpredictable quantity of segregated carbon on the metal surface. Nickel substrates, for example, have high carbon solubility and typically lead to multiple layers of low-quality graphene or disordered carbon. If the metal has low carbon solubility, carbon dissolves less easily in the metal and this results in an extensive surface migration of carbon atoms on the metal surface and minimal diffusion into bulk metal. This generally leads to more uniform graphene layers and fewer microstructural defects owing to more controlled growth. Copper substrates, for example, have low carbon solubility and result in epitaxial growth of high-quality graphene. The high-quality graphene may be grown as a single layer, bilayer, or few-layer graphene film.

Plasma-enhanced chemical vapor deposition (PECVD) is another method of depositing graphene. While thermal CVD methods activate hydrocarbon precursors by thermal decomposition, PECVD methods involve energized electrons generated by plasma that cause ionization, excitation, and dissociation of hydrocarbon precursors. The plasma may be formed in-situ or remotely. Hydrocarbon precursors (e.g., methane) may be activated in a plasma and a substrate is exposed to the plasma. The plasma may be generated using a radio-frequency (RF) plasma source, microwave (MW) plasma source, surface wave (SW) plasma source, or remote plasma source. In some embodiments plasma is generated using a capacitively coupled plasma. In some embodiments plasma is generated using an inductively coupled plasma. By way of an example, molecular hydrogen and methane gas may be introduced in a reaction chamber and direct RF plasma may be ignited to promote graphene growth on a substrate. With PECVD, graphene growth in some PECVD methods may be performed at lower temperatures compared to thermal CVD methods. Moreover, graphene growth in some PECVD methods may be accomplished on non-metal substrates such as dielectric materials. In other words, plasma-based methods may deposit graphene in the absence of metal catalysts. Plasma-based methods may deposit graphene at lower temperatures and without the assistance of metal catalysts.

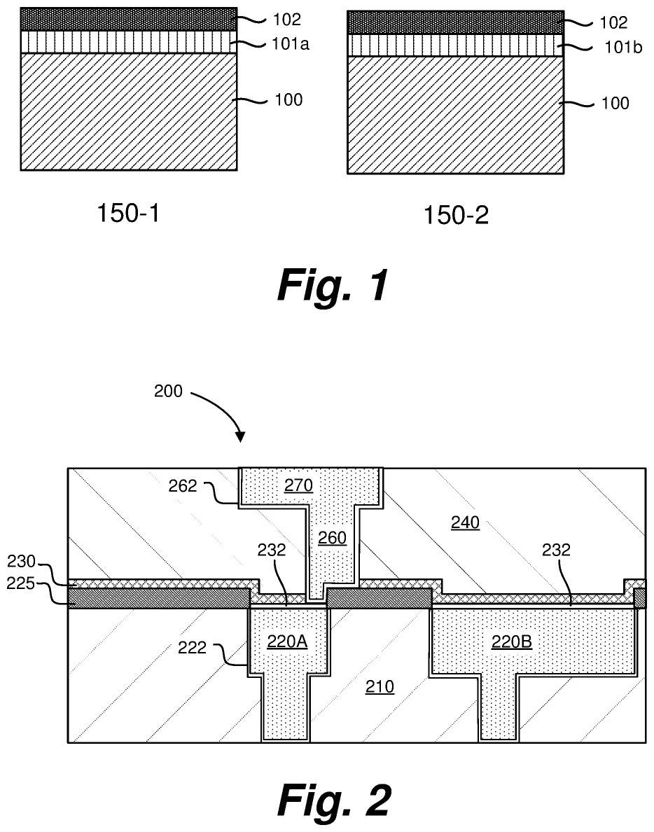

FIG. 1 illustrates two cross-sectional schematics of example substrates having a metal surface with graphene deposited thereon according to some implementations. For both structures 150-1 and 150-2, the substrate 100 can be any wafer, semiconductor wafer, partially fabricated integrated circuit, printed circuit board, display screen, or other appropriate workpiece. In some implementations, the substrate 100 is a semiconductor substrate such as a silicon (Si) substrate.

In structure 150-1, the substrate 100 can include a metal surface 101a. As discussed below, the metal surface 101a can also be referred to as a temperature sensitive underlayer. In some implementations, the metal surface 101a can include any appropriate metal such as a transition metal. For example, the metal surface 101a can include copper (Cu), ruthenium (Ru), nickel (Ni), molybdenum (Mo), cobalt (Co), or combinations thereof. A graphene film 102 can be deposited on the metal surface 101a.

In some implementations, depositing the graphene film 102 on the metal surface 101a of the substrate 100 may be accomplished by remote hydrogen plasma CVD and introduction of a carbon-containing precursor. The carbon-containing precursor may be activated by the remote hydrogen plasma. In some other implementations, depositing the graphene film 102 on the metal surface 101a of the substrate 100 may be accomplished using any suitable deposition technique such as thermal CVD or PECVD. A remote hydrogen plasma CVD method may deposit the graphene film 102 at low temperatures that are compatible with semiconductor processing, such as back end of line (BEOL) semiconductor processing. In some implementations, the graphene film 102 may be deposited at temperatures of about 200° C. to about 500° C., or below about 500° C., below about 450° C., below about 400° C., below about 350° C., below about 300° C., or about 200° C. to about 400° C.

When depositing the graphene film 102 using remote hydrogen plasma CVD, a hydrocarbon precursor is flowed to the metal surface 101a of the substrate 100 and hydrogen radicals are generated in a remote plasma source upstream of the hydrocarbon precursor flow. The hydrogen radicals interact with the hydrocarbon precursor to activate the hydrocarbon precursor downstream from the remote plasma source, and the activated hydrocarbon precursor interacts with the metal surface 101a to cause graphene film 102 to deposit. In some implementations, the hydrocarbon precursor includes an alkene group or alkyne group.

In some implementations of the present disclosure, such as in structure 150-2, the substrate 100 can include a temperature sensitive underlayer or structure 101b. References to the temperature sensitive underlayer herein may also include a temperature sensitive structure. The temperature sensitive underlayer 101b may have an upper bound temperature limit. Above the temperature limit of the temperature sensitive underlayer 101b, the temperature sensitive underlayer 101b may melt or may move from its intended location or otherwise be undesirably changed. The temperature limit may be at least about 200° C. or at least about 400° C. for many materials of the temperature sensitive underlayer 101b. Other layers in the structure may also have temperature limits. For example, in some embodiments, low-k dielectric may be present in the structure and may have an upper temperature limit of about 500° C. In some embodiments, structural damage may occur when combining different materials with different co-efficients of thermal expansion. Example structural damage include but are not limited to cracking, movement, or delamination.

Some thermal CVD methods and some conventional plasma-based CVD methods may exceed the temperature sensitive limit of the temperature sensitive underlayer 101b. Examples of a temperature sensitive underlayer 101b can include transition metals. In some implementations, a graphene film 102 is deposited on the temperature sensitive underlayer 101b. In some implementations, the graphene film 102 is deposited at sufficiently low temperatures that do not melt or otherwise physically damage the temperature sensitive underlayer 101b. The substrate 100 may be a semiconductor wafer or semiconductor workpiece. Hence, the graphene film 102 may be deposited as a large-area graphene film on the substrate 100.

In some implementations, the graphene film 102 is deposited using remote hydrogen plasma CVD. As used herein, the term “remote” in literature may generally refer to the remoteness of the substrate from the plasma. As used herein, a “remote plasma” may refer to a plasma in which plasma generation occurs at a location that is remote from the substrate. Here, the remote hydrogen plasma may contain hydrogen radicals but does not contain carbon radicals. Instead, carbon radicals are generated downstream from a remote plasma source. This means that in the “remote plasma” of some implementations, precursor gas is not introduced into the plasma-generating region. Hydrocarbon precursors are independently flowed into a reaction chamber and are activated by hydrogen radicals generated from the remote plasma source. Moreover, the resulting carbon radicals are generated from hydrocarbon precursors containing alkene or alkyne groups. In some embodiments, no deposition occurs on, for example, silicon wafers. In some embodiments, graphene deposits on certain metals. When using the remote hydrogen plasma CVD method, graphene deposition selectively deposits on metal surfaces. Graphene does not deposit on dielectric or other non-metal surfaces. Graphene does not deposit on barrier material, such as tantalum nitride. The remote hydrogen plasma CVD method is an example method that can deposit high-quality graphene film at low temperatures suitable for semiconductor applications. For example, a high-quality graphene film can serve as a barrier layer in damascene or dual damascene structures. Further, the high-quality graphene can serve as a capping layer on top of the metal surface can reduce electron scattering. However, it will be understood that the high-quality graphene film may be used in a wide number of industrial applications, such as fabrication of fully aligned vias.

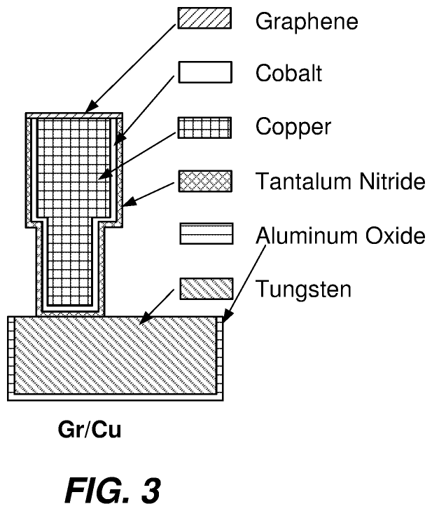

FIG. 2 shows a cross-sectional schematic illustration of an example semiconductor device having a graphene film and a dielectric layer in a dual damascene structure according to some implementations. A semiconductor device 200 includes a first dielectric layer 210 and a first metal layer 220A formed in the first dielectric layer 210. The semiconductor device 200 may further include a neighboring first metal layer 220B formed in the first dielectric layer 210, where the first metal layer 220A is adjacent to the neighboring first metal layer 220B without contacting the neighboring first metal layer 220B. Each of the first metal layer 220A and the neighboring first metal layer 220B is lined with a first barrier layer 222. The first barrier layer 222 may provide a diffusion barrier layer and/or liner layer at an interface between the first metal layer 220A and the first dielectric layer 210 as well as between the neighboring first metal layer 220B and the first dielectric layer 210.

In some implementations, each of the first metal layer 220A and the neighboring first metal layer 220B includes copper, cobalt, ruthenium, nickel, molybdenum, or combinations thereof. For example, each of the first metal layer 220A and the neighboring first metal layer 220B includes copper. In some implementations, the first dielectric layer 210 includes any suitable dielectric material such as silicon oxide or doped silicon carbide.

The semiconductor device 200 further includes a selective graphene film 232 formed on an exposed surface of the first metal layer 220A. The selective graphene film 232 is selectively deposited on the first metal layer 220A relative to the first dielectric layer 210. In some implementations, the selective graphene film 232 is also formed on an exposed surface of the neighboring first metal layer 220B. The selective graphene film 232 may have a thickness of about 3 Å to about 20 Å or about 5 Å to about 10 Å. The selective graphene film 232 is deposited on the top surface of the first metal layer 220A by flowing one or more hydrocarbon precursors toward the semiconductor device 200, generating from a hydrogen source gas radicals of hydrogen in a remote plasma source, and introducing the radicals of hydrogen toward the semiconductor device 200, where the radicals of hydrogen are introduced upstream from the one or more hydrocarbon precursors, where the radicals of hydrogen react with the one or more hydrocarbon precursors in an environment adjacent to at least the first metal layer 220A to deposit the selective graphene film 232. The one or more hydrocarbon precursors may each include an alkene or alkyne group. In some instances, the hydrogen source gas may be provided in a helium carrier at a concentration of about 1% to about 25% hydrogen or about 1% to about 10% hydrogen. The selective graphene film 232 is deposited at a low deposition temperature, where the low deposition temperature may be about 200° C. to about 600° C., or about 200° C. to about 400° C., or about 250° C. to about 400° C., or about 200° C. to about 300° C.

The semiconductor device 200 further includes a dielectric layer 225 formed on a top surface of the first dielectric layer 210. The dielectric layer 225 is deposited on the first dielectric layer 210. In some embodiments, the dielectric layer 225 is selectively deposited on the first dielectric layer 210 relative to the first metal layer 220A and the neighboring first metal layer 220B. The dielectric layer 225 may have a thickness of about 1 nm to about 10 nm. In some implementations, the dielectric layer 225 includes a low-k dielectric material such as silicon oxynitride, silicon oxycarbide, or silicon oxycarbonitride. In some implementations, the dielectric layer 225 is deposited on the first dielectric layer 210 using a non-direct plasma deposition technique such as remote hydrogen plasma CVD.

In some implementations, the semiconductor device 200 further includes an etch stop layer 230 over the dielectric layer 225 and the selective graphene film 232, where the etch stop layer 230 includes a metal oxide. In some embodiments, dielectric layer 225 may be an etch stop layer, such as metal oxide. In some embodiments, an etch stop layer may have already been deposited prior to depositing graphene. Examples of metal oxides include aluminum oxide, hafnium oxide, zirconium oxide, yttrium oxide, zinc oxide, titanium oxide, or combinations thereof. In some implementations, the etch stop layer 230 includes aluminum oxide. The etch stop layer 230 may have a thickness of about 5 Å to about 30 Å. In some implementations, the etch stop layer 230 is deposited over the dielectric layer 225 and the selective graphene film 232 using a thermal deposition technique such as thermal ALD or thermal CVD.

The semiconductor device 200 may further include a second dielectric layer 240 over the etch stop layer 230. The second dielectric layer 240 includes any suitable dielectric material such as low-k dielectric, silicon oxide, undoped silicon carbide, doped silicon carbide, or combinations thereof. The etch stop layer 230 may have an etch selectivity different than the second dielectric layer 240. For example, the etch stop layer 230 may have an etch resistance equal to or greater than ten times that of an etch resistance of the second dielectric layer 240 when one or more recesses are formed in the second dielectric layer 240. That way, etching through the second dielectric layer 240 does not result in etching the selective graphene film 232. The dielectric layer 225 may have an etch selectivity different than the etch stop layer 230.

Recesses and openings are formed through the second dielectric layer 240 and filled with an electrically conductive material to form a via 260 and a second metal layer 270 over the via 260. The second metal layer 270 is positioned over the first metal layer 220A, and the via 260 is positioned between the selective graphene film 232 and the second metal layer 270. The via 260 provides electrical interconnection between the first metal layer 220A and the second metal layer 270. The via 260 and the second metal layer 270 may be lined with a second barrier layer 262. The second barrier layer 262 may provide a diffusion barrier layer and/or liner layer at an interface between the via 260 and the second dielectric layer 240 as well as between the neighboring second metal layer 270 and the second dielectric layer 240. In some implementations, each of the via 260 and the second metal layer 270 includes copper, cobalt, ruthenium, nickel, molybdenum, or combinations thereof. For example, each of the via 260 and the second metal layer 270 includes copper.

As shown in FIG. 2, the selective graphene film 232 is positioned at an interface between the via 260 and the first metal layer 220A. The selective graphene film 232 serves as an inhibitor so that the dielectric layer 225 is deposited on the first dielectric layer 210 relative to the first metal layer 220A and the neighboring first metal layer 220B. The selective graphene film 232 is not removed after the dielectric layer 225 is deposited. The selective graphene film 232 lowers an electrical resistance at the via 260 because of reduced electron scattering. The dielectric layer 225 ensures that the via 260 is a filly aligned via, and the dielectric layer 225 provides additional spacing between the via 260 and the neighboring first metal layer 220B.

Provided herein are methods and apparatuses for forming copper interconnects with a graphene cap which is formed directly on copper. Certain embodiments are directed to deposition of graphene on metal substrates such as copper, at BEOL-compatible temperatures (such as about 400° C. or lower) using a remote plasma activation of a hydrocarbon precursor. Certain disclosed embodiments are particularly suitable for graphene integration into BEOL copper structures or interconnects.

Certain disclosed embodiments are directed to graphene cap formation in a BEOL-compatible temperature range (which may be less than about 400° C.) having superior performance (electromigration (EM) and line resistance) of graphene-capped copper interconnects in scaled metal critical dimension (CD) in future technology nodes, such as 5 nm and beyond. An etch stop layer (ESL) may be deposited on top of or over the graphene without damaging the graphene quality. In some embodiments, graphene-capped copper dual damascene interconnects may be integrated on wafers having a CD range of less than about 15 nm or about 15 nm.

One or more layers of graphene growth may be formed directly on copper using certain disclosed embodiments. Graphene growth involves activation of hydrocarbons (such as alkenes and alkynes) downstream using a remote plasma. Certain disclosed embodiments involve surface preparation, plasma, and generation of carbon radicals to allow graphene growth at low temperatures. Surface preparation reduces or eliminates damage on the growth surface due to subsequent plasma. In various embodiments, remote plasma is used on graphene on copper and cobalt using activation of hydrocarbon precursor by radicals.

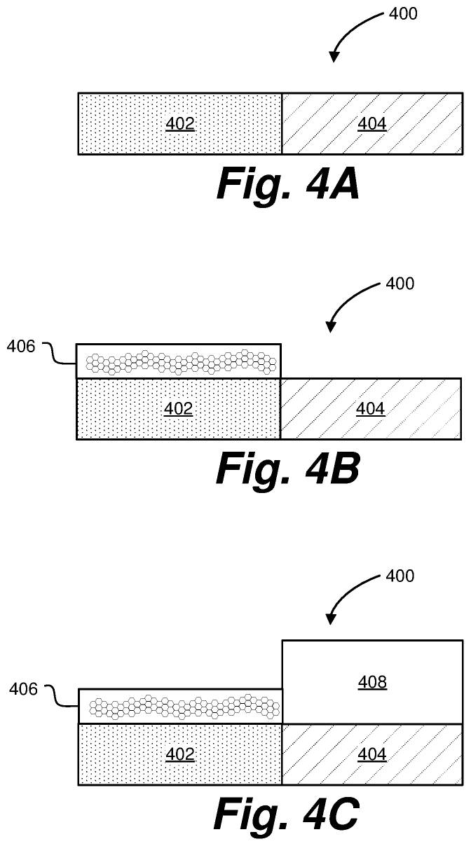

FIG. 3 shows an example structure having graphene deposited thereon. The structure includes a copper interconnect with a graphene cap on top of a copper surface. In some embodiments, growth on copper may be surface-mediated. In some embodiments, deposition of graphene on copper may result in high quality graphene films. For example, graphene deposited on copper may include carbon that is all sp2 hybridized. Without being bound by a particular theory, it is believed that graphene deposition on copper results in better quality because the electron configuration of copper is more easily stabilized by an electron, thereby forming substantially all or mostly sp2 hybridized carbon in the graphene film, whereas the electron configuration of cobalt results in four remaining, less stable electrons.

In various embodiments, the temperature during deposition of graphene may be less than about 1000° C. or less than about 400° C.

### Integration of Graphene in Dual Damascene

In certain embodiments described herein, about one to two layers of graphene directly on copper may be deposited. In some embodiments, graphene is deposited using a temperature of about 200° C. to about 400° C. In various embodiments, graphene deposition is uniform or conformal.

Certain disclosed embodiments allow graphene to grow selectively on the metal line and not on exposed dielectric. Certain disclosed embodiments allow deposition of graphene selectively on non-cobalt metal relative to dielectric. In various embodiments, the growth is self-limiting. For example, in some embodiments, the deposition thickness may be about 3 monolayers or about 2 monolayers. Certain disclosed embodiments deposit graphene while minimizing damage to low-k material adjacent to the metal.

Certain embodiments herein involve selective deposition of graphene. Graphene may be selectively deposited on metal surfaces relative to dielectric surfaces. Graphene may be selectively deposited on cobalt-free metal surfaces relative to dielectric surfaces. In some embodiments, graphene acts as an inhibitor that promotes selective deposition of materials on the dielectric surfaces while inhibiting deposition on the metal surfaces. Graphene films are generally stable at elevated temperatures. Graphene films may be incorporated during semiconductor integration since graphene films deposited on metal surfaces may lower an effective resistivity of metal lines due to reduced electron scattering. In some implementations, graphene films do not necessarily require subsequent removal in semiconductor manufacturing applications. In some other implementations, however, graphene may be removed after selective deposition of the dielectric material, and subsequent deposition operations may occur anywhere.

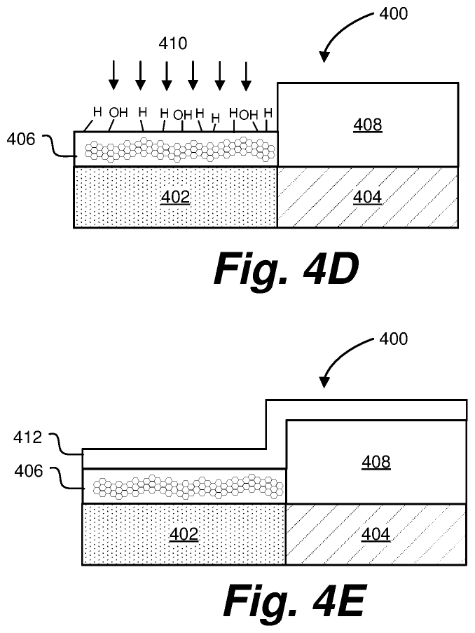

FIG. 4A illustrates a cross-sectional schematic of an example semiconductor substrate 400 including a dielectric layer 404 adjacent to a metal layer 402. In some implementations, the metal layer 402 may be formed in the dielectric layer 404, where the dielectric layer 404 may be an interlayer dielectric for a damascene or dual damascene structure. A recess may be etched through the dielectric layer 404, where the recess may be patterned and formed using a suitable lithography process. The recess may be filled with an electrically conductive material to form the metal layer 402. In some implementations, the metal layer 402 includes copper, ruthenium, aluminum, nickel, cobalt, tungsten, molybdenum, or combinations thereof. A diffusion barrier layer and/or liner layer may be lined between the metal layer 402 and the dielectric layer 404. The diffusion barrier layer may limit diffusion of metal atoms into the dielectric layer 404. Each of the metal layer 402 and the dielectric layer 404 have exposed top surfaces.

FIG. 4B illustrates a cross-sectional schematic of the semiconductor substrate 400 of FIG. 4A, where a graphene film 406 is selectively deposited on the metal layer 402. The graphene film 406 is formed directly on the metal layer 402 without being formed, placed, or otherwise positioned on the dielectric layer 404. The graphene film 406 may include high-quality graphene, where the graphene film 406 is a single layer graphene film, bilayer graphene film, or few layer graphene film. The graphene film 406 may be free of defective sites on which deposition precursors of dielectric materials may nucleate. The electrically conductive properties of the graphene film 406 may lower the effective resistivity of the metal layer 402 when electrically connected to a via (not shown) due to reduced electron scattering. In some implementations, the graphene film 406 may be deposited using a remote hydrogen plasma CVD process as described above. In some implementations, the graphene film 406 may be deposited at a low deposition temperature of about 200° C. to about 300° C. In some implementations, the graphene film 406 has a thickness of about 3 Å to about 20 Å or about 5 Å to about 10 Å.

FIG. 4C illustrates an example of a cross-sectional schematic of the semiconductor substrate 400 of FIG. 4B, where a first dielectric material 408 is selectively deposited on the dielectric layer 404. The first dielectric material 408 is deposited on the dielectric layer 404 without being formed, placed, or otherwise positioned on the top surface of the graphene film 406. The graphene film 406 inhibits deposition of the first dielectric material 408 on the metal layer 402. In some implementations, the first dielectric material 408 may be deposited in a manner that is non-damaging to the graphene film 406. In some implementations, the first dielectric material 408 may include a metal oxide such as aluminum oxide, where the metal oxide may be deposited using a thermal-based deposition technique such as ALD. In some implementations, the metal oxide may have a thickness of about 5 Å to about 100 Å, or about 5 Å to about 60 Å. The first dielectric material 408 may serve as an etch stop layer. In some implementations, the first dielectric material 408 may include a dielectric material such as silicon oxycarbide, silicon oxynitride, or silicon oxycarbonitride, where the dielectric material may be deposited by a non-direct plasma deposition technique such as remote hydrogen plasma CVD. In some implementations, the dielectric material may have a thickness of about 1 nm to about 10 nm. The first dielectric material 408 may serve as a spacer layer in a fully aligned patterning scheme. In some embodiments, the dielectric material for first dielectric material 408 is a low-k material having a k value of about 2.5 to about 3.0 In some embodiments, the material for the first dielectric material 408 is an etch stop material which may also function as a dielectric diffusion barrier. The etch stop material may have a k value of greater than about 4.0. In some embodiments, such etch stop material may have higher density than a low-k dielectric material. Examples of etch stop materials include oxycarbides, SiCN, SiOCN, and combinations thereof.

FIG. 4D illustrates a cross-sectional schematic of the semiconductor substrate 400 of FIG. 4C, where the graphene film 406 is exposed to treatment conditions 410 to cause surface modification of the graphene film 406. This may be referred to as “functionalization.” The modified surface of the graphene film 406 may be characterized by more defective sites for nucleation, where the defective sites may include defective sites of hydrogen-terminated sites and/or hydroxyl-terminated sites. In some implementations, the treatment conditions 410 may include exposure to remote plasma such as a remote hydrogen plasma. The remote plasma may additionally or alternatively include oxygen, nitrogen, ammonia, or combinations thereof. In some implementations, the treatment conditions 410 include exposure to one or more deposition operations. Over enough deposition operations, the surface of the graphene film 406 may eventually become functionalized so that nucleation can take place on the graphene film 406. In some implementations, the treatment conditions 410 include exposing the graphene film 406 to enough delay for the graphene film 406 to degrade in quality over time. Such treatment conditions 410 may include, for example, exposing the graphene film 406 to an air break for an extended duration. Though not shown in FIG. 4D, the graphene film 406 may alternatively be removed rather than modified. Removing the graphene film 406 may facilitate subsequent deposition anywhere on the semiconductor substrate 400 without the graphene film 406 serving as an inhibitor.

FIG. 4E illustrates a cross-sectional schematic of the semiconductor substrate 400 of FIG. 4D, where a second dielectric material 412 is deposited over the graphene film 406 and the first dielectric material 408. The graphene film 406 may be conditioned to promote deposition following the treatment conditions 410 in FIG. 4D. In some implementations, the second dielectric material 412 includes a metal oxide such as aluminum oxide, hafnium oxide, zirconium oxide, yttrium oxide, zinc oxide, titanium oxide, or combinations thereof. The metal oxide may be deposited by a thermal-based deposition technique such as thermal ALD. The metal oxide may serve as an etch stop layer. In some implementations, the second dielectric material 412 includes a hermetic barrier such as silicon oxycarbide, silicon carbonitride, or silicon oxycarbonitride. The hermetic barrier may be deposited by a non-direct plasma deposition technique such as remote hydrogen plasma CVD. The hermetic barrier may serve to encapsulate and protect the graphene film 406. It will be understood that in implementations where the graphene film 406 is removed, the second dielectric material 412 may be deposited using any suitable deposition technique. The second dielectric material 412 may be deposited over the metal layer 402 and the first dielectric material 408.

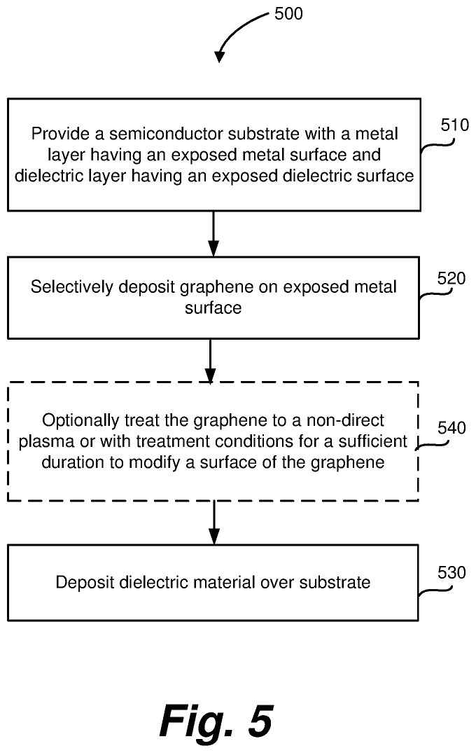

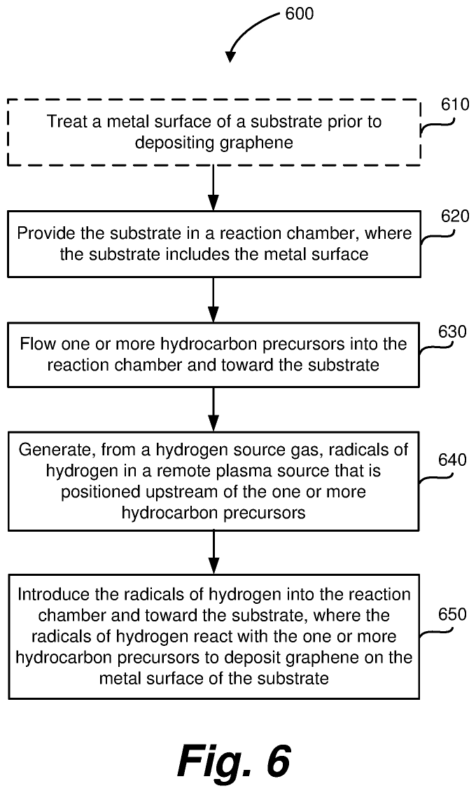

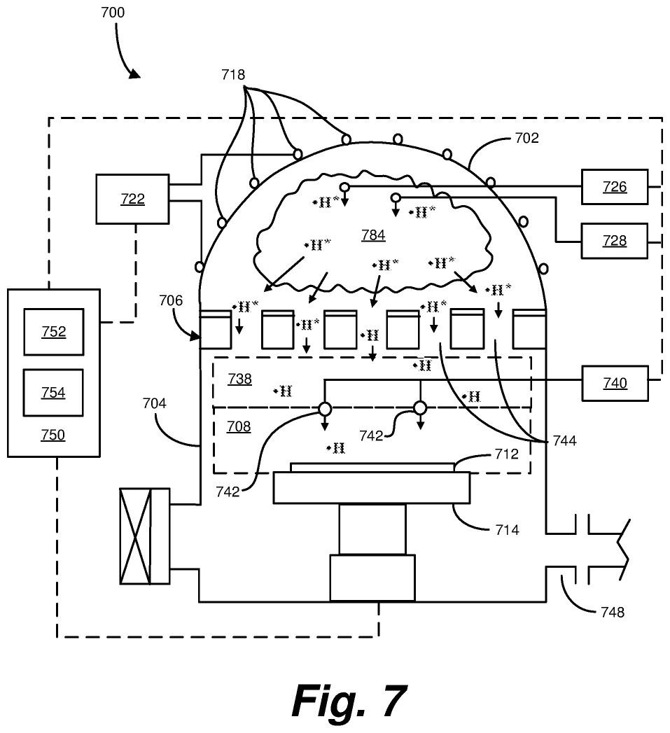

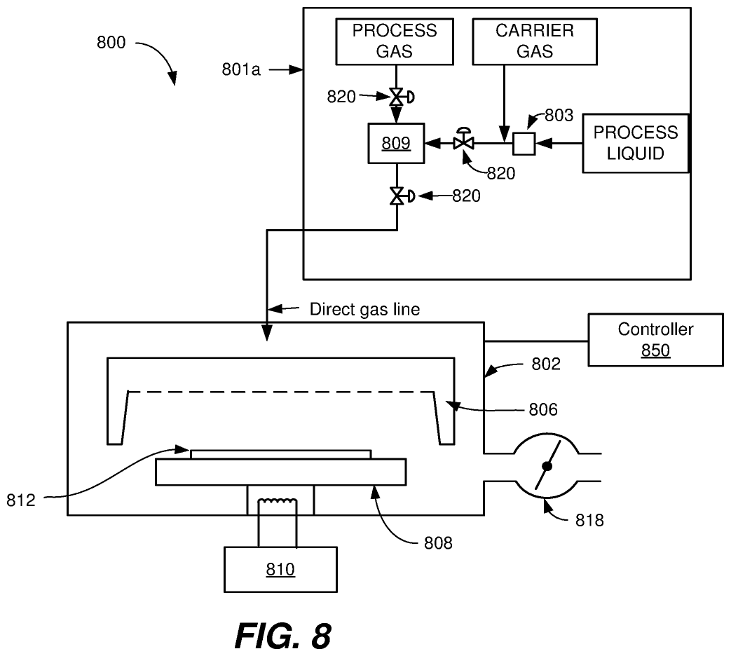

FIG. 5 illustrates a flow diagram of an example method of selective deposition using graphene according to some implementations. The operations of a process 500 may be performed in different orders and/or with different, fewer, or additional operations. The operations of the process 500 are described with reference to an example process of selective deposition in FIG. 6. One or more operations of the process 500 may be performed using a plasma processing apparatus shown in FIGS. 7 and 8. In some implementations, the operations of the process 500 may be implemented, at least in part, according to software stored in one or more non-transitory computer readable media.

Process 500 includes an operation 510 where a semiconductor substrate is provided, where the semiconductor substrate includes a metal layer formed in a dielectric layer. In various embodiments, the semiconductor substrate has a partially fabricated metal interconnect, such as a copper interconnect or a cobalt-capped copper interconnect. The metal layer has an exposed metal surface. In various embodiments, the metal layer includes copper, or cobalt.

The semiconductor substrate may be a silicon wafer, such as a 200-mm wafer, 300-mm wafer, or a 450-mm wafer, including wafers having one or more layers of material, such as dielectric, conducting, or semiconducting materials deposited thereon. The dielectric layer may have a k value of about 4. In some embodiments, the dielectric layer may be a low-k dielectric material such as silicon oxide or doped silicon carbide. Low-k dielectric materials may have a dielectric constant equal to or less than about 4.0. In some implementations, the dielectric layer may be an ultralow-k dielectric material such as a fluorine-doped or carbon-doped silicon oxide. Ultralow-k dielectric materials may have a dielectric constant equal to or less than about 2.5.

In some implementations, the metal layer may be a metallization layer in a metallization scheme, where the metal layer may include any suitable electrically conductive material such as copper, ruthenium, aluminum, nickel, cobalt, tungsten, molybdenum, or combinations thereof. In some implementations, the metal layer may be treated prior to deposition of graphene on the metal layer, where treatment may serve to at least polish the metal layer and/or remove impurities. For example, the exposed metal surface of the metal layer may be exposed to a reducing agent to reduce metal oxides and carbon residues. In some embodiments, the metal layer is copper.

In some implementations, a barrier layer is formed between the metal layer and the dielectric layer. The barrier layer may be a transition metal nitride. The barrier layer may be a mixture of metal and metal nitride material in some embodiments. In some embodiments, the barrier layer is a tantalum-containing layer. In some embodiments, the barrier layer is a tantalum nitride. In some embodiments, the barrier layer is a mixture of tantalum metal and tantalum nitride. In some embodiments, the barrier layer is a tungsten-containing layer. Other examples of barrier layer materials include tungsten and tungsten nitride.

Returning to FIG. 5, process 500 includes an operation 520 whereby graphene is selectively deposited on the exposed metal surface. In various embodiments, graphene is selectively deposited directly on an exposed copper surface. The graphene is selectively deposited on the exposed metal surface relative to other surfaces, including dielectric surfaces. In some implementations, the graphene is selectively deposited on the exposed metal surface using a remote hydrogen plasma CVD process, thermal CVD process, PECVD process, or another suitable deposition process. For example, the graphene may be selectively deposited on the exposed metal surface using a remote hydrogen plasma CVD process as described above.

In some implementations, the graphene deposited on the exposed metal surface is high-quality graphene. High-quality graphene may have carbon atoms that are most or all sp2 hybridized. High-quality graphene can help reduce line resistance and potentially prevent electromigration. In some cases, high-quality graphene can be later treated to form sites on which subsequent films, such as a dielectric material or aluminum oxide material, can nucleate. This can also allow selective deposition of other materials such that deposition forms on non-graphene surfaces relative to graphene surfaces, because without defective sites such as hydrogen-terminated sites or hydroxyl-terminated sites on high-quality graphene, various precursors are unable to nucleate on the surface of the graphene. For example, ALD or CVD of metal oxides may be unable to nucleate on high-quality graphene if precursors for such metal oxides are unable to adsorb on the high-quality graphene. High-quality graphene may be characterized by being free or substantially free of hydrogen-terminated sites and hydroxyl-terminated sites. High-quality graphene may be characterized by a 2D peak that is significantly greater than a G peak in a Raman spectrum, and a D peak that is negligible in the Raman spectrum. In some implementations, the 2D peak is at least two times greater than the G peak in the Raman spectrum.

In some implementations, the graphene may be selectively deposited on the exposed metal surface without depositing on an adjacent dielectric layer. Selectively depositing the graphene on the exposed metal surface may include flowing one or more hydrocarbon precursors into a reaction chamber and towards the semiconductor substrate, generating radicals of hydrogen in a remote plasma source from a hydrogen source gas, and introducing the radicals of hydrogen into the reaction chamber and towards the semiconductor substrate, where the radicals of hydrogen react with the one or more hydrocarbon precursors to deposit the graphene on the exposed metal surface. The one or more hydrocarbon precursors are provided downstream from the radicals of hydrogen. In some implementations, the one or more hydrocarbon precursors include an alkene or alkyne group. This type of deposition process avoids damage to the BEOL structure, as utilization of radicals during deposition both reduces and eliminates damage to the surface structure and reduces the temperature at which this deposition can be performed. For example, such deposition may be performed at a temperature of less than about 400° C.

Graphene may be deposited under conditions where the semiconductor substrate is maintained at a deposition temperature less than a semiconductor processing temperature limit during selective deposition of the graphene. In some implementations, the semiconductor processing temperature limit may correspond to a temperature sensitive limit of materials or components in the semiconductor substrate. For example, the temperature limit may be about 400° C. for copper. In some implementations, the semiconductor processing temperature limit is about 400° C. Thus, the deposition temperature may be less than about 400° C., less than about 350° C., less than about 300° C., about 200° C. to about 400° C., or about 200° C. to about 300° C.

Higher temperatures may reduce the quality of graphene. Graphene may be deposited and processed under conditions so that the graphene causes nucleation delay. Not only does deposition temperature affect the properties of graphene, but deposition time, precursor flow rate, and other parameters can influence the properties of graphene. Generally speaking, shorter deposition times and higher precursor flow rates can provide graphene with improved nucleation delay.

Returning to FIG. 5, in an operation 540 of the process 500, the graphene may be optionally treated with a non-direct plasma or with treatment conditions for a sufficient duration to modify a surface of the graphene. The surface of the graphene may be modified to promote subsequent deposition on the graphene. The surface may be modified so as to facilitate nucleation of dielectric over the graphene. For example, in some embodiments, the treatment functionalizes the surface of the graphene so that nucleation may occur on the graphene.

In some implementations, the treatment includes exposing the graphene with the non-direct plasma. Exposing the graphene to direct or in-situ plasmas etches the graphene or destroys the graphene crystalline structure to form disorganized or amorphous carbon. Exposing the graphene to non-direct or remote plasmas may functionalize the surface of the graphene without etching the graphene. In some implementations, the non-direct plasma may be a remote hydrogen plasma including radicals of hydrogen (e.g., H₂ plasma). In some implementations, the non-direct plasma may be a remote plasma including radicals of hydrogen mixed with radicals of oxygen, nitrous oxide, nitric oxide, carbon dioxide, carbon monoxide, water, ozone, peroxides, ammonia, nitrogen, or combinations thereof (e.g., H₂/O₂ plasma). The semiconductor substrate may be maintained at a low treatment temperature during exposure to the non-direct plasma. In some implementations, the treatment temperature may be about 20° C. to about 400° C. or about 20° C. to about 200° C. After exposure to the non-direct plasma at the low treatment temperature, the surface of the graphene may have defective sites such as hydrogen-terminated sites or hydroxyl-terminated sites to promote nucleation and growth of subsequent material deposition on the graphene. In some implementations, the treatment at operation 540 and the selective dielectric deposition at operation 530 may be performed in the same reaction chamber or tool so that a vacuum break is not introduced between operations at operations 530 and 540.

In some implementations, the treatment includes exposing the graphene under treatment conditions for a sufficient duration. The treatment conditions may include exposing the graphene to one or more gases for an extended duration. The one or more gases may include one or both of hydrogen and oxygen. For example, the graphene may be exposed to atmospheric conditions with an air break. Without being limited by any theory, the air break may allow oxygen and/or water molecules to functionalize the surface of the graphene. In some implementations, the treatment conditions may include exposure to atmospheric pressure (760 Torr) or less, exposure to air, and exposure to approximately room temperature (about 15° C. to about 25° C.). An extended duration of at least about 2 minutes, at least about 5 minutes, at least about 10 minutes, or at least about 15 minutes is a sufficient duration to adequately functionalize the surface of the graphene. In some implementations, the treatment conditions include one or more deposition operations. The surface of the graphene may at least be partially functionalized after selectively depositing the dielectric material on the dielectric layer. Furthermore, the surface of the graphene may be more functionalized after performing additional deposition operations on the semiconductor substrate. Over an extended time or after sufficient deposition operations, enough defective sites of hydrogen-terminated sites and/or hydroxyl-terminated sites may form on the surface of the graphene to promote nucleation and growth of subsequent material deposition on the graphene.

In some implementations, the treatment conditions allow subsequent deposition of an ultra-thin layer on graphene, where the ultra-thin layer promotes subsequent material deposition on the graphene. For example, such an ultra-thin layer can include aluminum oxide itself deposited by CVD. In some embodiments, the ultra-thin layer can include silicon carbonitride, silicon oxycarbide, or silicon nitride.

Returning to FIG. 5, the process 500 may further include depositing a dielectric material on by a thermal-based deposition technique. A thickness of metal oxide may be about 5 Å to about 100 Å or about 5 Å to about 60 Å. Alternatively, the process 500 may further include depositing a hermetic barrier by a non-direct plasma deposition technique. A thickness of the hermetic barrier may be about 5 Å to about 100 Å. The metal oxide or the hermetic barrier may be deposited on the modified surface of the graphene and the dielectric layer where the graphene remains intact. In some embodiments, during such operations, the graphene layer may be reduced in thickness due to exposure to particular processing conditions during deposition of the dielectric, but the reduction in thickness does not cause mushrooming or overhang.

In some implementations, the dielectric is deposited by thermal ALD, thermal CVD, or physical vapor deposition (PVD). Deposition of the dielectric may occur at a temperature below the semiconductor processing temperature limit. In various embodiments, the dielectric is a metal oxide. In some instances, deposition of the metal oxide may improve crystalline properties of the underlying graphene. The metal oxide may include aluminum oxide, hafnium oxide, zirconium oxide, yttrium oxide, zinc oxide, titanium oxide, or combinations thereof. For example, the metal oxide includes aluminum oxide. Deposition of aluminum oxide may occur by thermal ALD by introducing a dose of an aluminum-containing precursor such as trimethyl aluminum (TMA) and exposing the semiconductor substrate to an oxidant such as ozone or water. The metal oxide may serve as an etch stop. The metal oxide may additionally or alternatively serve as a protective layer for graphene against potentially damaging plasmas. In some implementations, where the dielectric material selectively deposited on the dielectric layer is a low-k dielectric material, the metal oxide is deposited on the low-k dielectric material and the graphene or on the low-k dielectric material and the metal layer. The metal oxide has a different etch selectivity than the low-k dielectric material, and a thickness of the low-k dielectric material is at least two times greater than a thickness of the metal oxide.

In some implementations, deposition of the metal oxide on the graphene may be followed by deposition of a hermetic barrier. The hermetic barrier may be deposited by any suitable deposition technique including non-direct and direct plasma deposition techniques. The metal oxide over the graphene may protect the graphene from exposure to damaging plasmas. Thus, the hermetic barrier may be deposited using PECVD or PEALD, where the plasma may be generated in-situ or remotely.

In some implementations, a hermetic barrier such as nitrogen-doped silicon carbide, oxygen-doped silicon carbide, or silicon nitride is deposited. Where the hermetic barrier is deposited over graphene, deposition may occur by a non-direct plasma deposition technique. The non-direct plasma deposition technique may be a remote plasma CVD technique. Where the hermetic barrier layer is deposited after removal of graphene, deposition may occur using any suitable deposition technique. The hermetic barrier may serve as an etch stop and as a hermetic barrier. In some implementations, the hermetic barrier may provide protection to the graphene by sealing the graphene from water, oxygen, and other chemistries in a surrounding environment that may adversely affect the film properties of graphene.

In a remote plasma CVD technique, a silicon-containing precursor is flowed to the semiconductor substrate in a reaction chamber, radicals are generated in a remote plasma source from a source gas, and the radicals are introduced into a reaction chamber and flowed to the semiconductor substrate to react with the silicon-containing precursor in the reaction chamber, thereby forming the hermetic barrier. In some implementations, the source gas includes hydrogen gas (H₂) and the radicals include hydrogen radicals. The radicals are provided under processing conditions so that the radicals are in a substantially low energy state or ground state when reacting with the silicon-containing precursor in an environment adjacent to the semiconductor substrate.

The radicals are generated in the remote plasma source upstream from the silicon-containing precursor. The silicon-containing precursor contains silicon-hydrogen bond(s) and/or silicon-silicon bond(s), and silicon-carbon bond(s), silicon-nitrogen bond(s), and/or silicon-oxygen bond(s). In some implementations, the silicon-containing precursor does not contain carbon-oxygen bonds or carbon-nitrogen bonds. By having the radicals generated upstream from the silicon-containing precursor and in a remote plasma source, the semiconductor substrate is not directly exposed to plasma.

In various embodiments, interconnects having graphene-capped copper, or graphene-capped cobalt on copper, may exhibit superior properties. For example, such interconnects may have short time-to-failure compared to copper interconnects without a graphene cap.

In various embodiments, in graphene-capped cobalt on copper, there may be less than 1% or no carbon at the cobalt-copper interface.

### Graphene Deposition

FIG. 6 illustrates a flow diagram of an example method of depositing graphene on a metal surface of a substrate according to some implementations. The operations of a process 600 may be performed in different orders and/or with different, fewer, or additional operations. In some embodiments, operations of process 600 are performed during operation 520 of FIG. 5. The operations of the process 600 may be performed using a plasma processing apparatus shown in FIG. 7. In some implementations, the operations of the process 600 may be implemented, at least in part, according to software stored in one or more non-transitory computer readable media.

In an operation 610 of the process 600, a metal surface of a substrate may be optionally treated prior to depositing graphene. Graphene deposition can depend on the smoothness and purity of the metal surface on which graphene is grown. Surface preparation techniques may be applied on the metal surface to polish the substrate and remove impurities. Polishing the substrate may be performed by a light etch in some implementations. Removal of impurities may be performed by a chemical treatment that removes, for example, metal oxides. Removal of impurities may additionally or alternatively involve removal of residues or contaminants from chemical mechanical planarization (CMP) processes. In some implementations, the treatment of the metal surface may occur before any diffusion barrier deposition, etch stop deposition, or hermetic barrier deposition.

In some implementations, treating the metal surface of the substrate can include exposing the metal surface to a plasma of a reducing gas species. Treatment of the metal surface can at least include removal of impurities and/or reduction of metal oxides by exposure to plasma. In some implementations, the plasma can include ions and radicals of a reducing gas species. Reducing gas species can include, for example, hydrogen gas (H₂), ammonia (NH₃), or combinations thereof. Thus, the metal surface may be treated by an H₂ plasma, NH₃ plasma, or H₂/NH₃ plasma. The plasma may be a direct (in-situ) plasma or remote plasma. In some implementations, exposing the metal surface to the plasma of the reducing gas species includes exposing the metal surface to a remote hydrogen plasma.

In some implementations, treating the metal surface further includes exposing the metal surface to a cyano-based radical species. In some other implementations, treating the metal surface includes exposing the metal surface to a cyano-based radical species as an alternative to exposing the metal surface to the reducing gas species. Cyano-based radical species may perform a light etch for smoothing the metal surface prior to graphene growth. Exposing the metal surface to the cyano-based radical species can occur before or after exposing the metal surface to the plasma of the reducing gas species. This can be referred to as a multi-step pretreatment process. The multi-step pretreatment process, or at least some steps of the multi-step pretreatment process, may be performed in the same or different apparatus than the plasma processing apparatus for depositing graphene. Exposing the metal surface to the cyano-based radical species can occur simultaneous with exposing the metal surface to the plasma of the reducing gas species. This can be referred to as a single-step pretreatment process. The single-step pretreatment process may be performed in the same or different apparatus than the plasma processing apparatus for depositing graphene.

In a multi-step pretreatment process, the cyano-based radical species may be generated by igniting a plasma, where the plasma may be a direct (in-situ) plasma or a remote plasma. The cyano-based radical species may be generated from a gas mixture containing at least a carbon-containing source gas and a nitrogen-containing source gas or from a gas mixture containing a precursor having a carbon-nitrogen (CN) bond. Thus, treating the metal surface can further include generating, from at least a carbon-containing source gas and a nitrogen-containing source gas or from a precursor having a carbon-nitrogen bond, plasma containing the cyano-based radical species. For example, a gas mixture of a hydrocarbon precursor, nitrogen gas, and hydrogen gas may be supplied to a plasma generator, and plasma of the gas mixture may be ignited to form the cyano-based radical species.

In a single step pretreatment process, the cyano-based radical species may be generated by activating a downstream carbon-containing precursor. Activation of the downstream carbon-containing precursor is simultaneous with surface pretreatment by the plasma of the reducing gas species. In such instances, a remote plasma source is positioned upstream of the downstream carbon-containing precursor, where the plasma of the reducing gas species is generated in the remote plasma source. In some implementations, the downstream carbon-containing precursor may be a hydrocarbon precursor. Thus, the downstream carbon-containing precursor may be chemically the same or different than the hydrocarbon precursor used in depositing graphene. In such cases, the plasma of the reducing gas species is a plasma of a reducing gas species and of a nitrogen-containing agent. For example, the reducing gas species can include hydrogen gas. The nitrogen-containing agent can include nitrogen gas. Hence, the plasma of the reducing gas species and of the nitrogen-containing agent can be a remote H₂ and N₂ plasma. The concentration of the reducing gas species may be greater than the concentration of the nitrogen-containing agent in the plasma. Without being limited by any theory, it is believed that ions/radicals of the nitrogen-containing agent interact with the downstream carbon-containing precursor to form the cyano-based radical species. The cyano-based radical species can perform a light etch for smoothing the metal surface and the plasma of the reducing gas species can reduce metal oxides to metal on the metal surface. In some other implementations, the downstream carbon-containing precursor may be precursor gas containing one or more CN bonds. Such a precursor may be activated by the plasma of the reducing gas species, where the plasma of the reducing gas species is a remote plasma generated upstream in the remote plasma source. In some instances, the plasma of the reducing gas species is a remote hydrogen plasma. Without being limited by any theory, it is believed that ions/radicals of hydrogen interact with the downstream carbon-containing precursor having one or more CN bonds to form the cyano-based radical species.

Though the treatment operation at an operation 610 may be described in terms of a multi-step pretreatment process and a single step pretreatment process, it will be understood that pretreatment of the metal surface is not limited to such techniques. The metal surface of the substrate may be pretreated prior to graphene deposition using any suitable surface preparation technique known in the art.

In an operation 620 of the process 600, the substrate is provided in a reaction chamber, where the substrate includes the metal surface. In some implementations, the substrate may already be provided in the reaction chamber during treatment at operation 610. The substrate may be a semiconductor substrate used in semiconductor applications. The metal surface can include any appropriate metal such as a transition metal. For example, the metal surface can include copper, ruthenium, nickel, molybdenum, cobalt, or combinations thereof. In some embodiments, the metal surface is cobalt-free. In some embodiments, the metal surface is copper. The metal surface can serve as a catalyst for promoting graphene nucleation and growth. Deposition of graphene may be selective to the particular metal of the metal surface. Put another way, deposition of graphene may not occur on dielectric surfaces or other non-metal surfaces.

The reaction chamber may include a substrate support or pedestal for supporting the substrate. A remote plasma source may be fluidly coupled to the reaction chamber via a showerhead. The metal surface of the substrate may be facing towards the remote plasma source. A precursor gas line may be separately fluidly coupled to the reaction chamber via one or more gas outlets. The one or more gas outlets may be located downstream from the remote plasma source. The one or more gas outlets may deliver hydrocarbon precursors into the reaction chamber and the remote plasma source may generate hydrogen radicals for delivery into the reaction chamber.

In an operation 630 of the process 600, one or more hydrocarbon precursors are flowed into the reaction chamber and towards the substrate. Each of the one or more hydrocarbon precursors includes an alkene or alkyne group. This means that the hydrocarbon precursors include one or more unsaturated carbon bonds, such as one or more carbon-to-carbon double bonds and/or carbon-to-carbon triple bonds. Examples of hydrocarbon precursors having alkene or alkyne groups include but are not limited to toluene, benzene, ethylene, propylene, butene, pentadiene (e.g., 1,4 pentadiene), hexene, acetylene, propyne, butyne, or pentyne. In some implementations, each of the one or more hydrocarbon precursors may include a carbon chain having at least 2 carbon atoms, at least 3 carbon atoms, at least 4 carbon atoms, at least 5 carbon atoms, at least 6 carbon atoms, or at least 7 carbon atoms.

The one or more hydrocarbon precursors may flow into the reaction chamber through the one or more gas outlets fluidly coupled to the reaction chamber. The one or more gas outlets are positioned downstream from the remote plasma source. Plasma of the one or more hydrocarbon precursors is not generated in the reaction chamber or in the remote plasma source. Rather, the one or more hydrocarbon precursors are flowed into the reaction chamber independently of plasma generated in the remote plasma source.

The one or more hydrocarbon precursors are flowed towards the substrate to adsorb onto the metal surface or at least positioned in an environment adjacent to the metal surface of the substrate. In some embodiments, the one or more hydrocarbon precursors are flowed towards the substrate and adsorb directly onto a copper surface or at least positioned in an environment adjacent to the copper surface of the substrate. In some implementations, the one or more hydrocarbon precursors are flowed into the reaction chamber simultaneous with plasma generation and plasma exposure as described at operations 640 and 650. In some implementations, the one or more hydrocarbon precursors are flowed into the reaction chamber prior to plasma generation and plasma exposure as described at operations 640 and 650.

In some implementations, the one or more hydrocarbon precursors are delivered with other species, notably carrier gas, into the environment adjacent to the metal surface of the substrate. Upstream from the deposition reaction surface, the one or more hydrocarbon precursors can be mixed with an inert carrier gas. Example inert carrier gases include, but are not limited to, argon (Ar) and helium (He). In some implementations, the one or more hydrocarbon precursors are delivered as a mixture of multiple hydrocarbon precursors. The multiple hydrocarbon precursors may be present in equimolar or relatively similar proportions as appropriate to form the primary backbone or matrix in the resulting graphene. In other implementations, the relative amounts of the multiple hydrocarbon precursors are substantially skewed from equimolarity.

In an operation 640 of the process 600, radicals of hydrogen are generated, from a hydrogen source gas, in a remote plasma source that is positioned upstream of the one or more hydrocarbon precursors. Specifically, the radicals of hydrogen are generated in a remote plasma source that is upstream from the one or more gas outlets for introducing the one or more hydrocarbon precursors into the reaction chamber. The remote plasma source may be any suitable plasma source for plasma generation, such as an inductively-coupled plasma source or capacitively-coupled plasma source. In some implementations, the hydrogen source gas is hydrogen gas (H₂). In some implementations, the hydrogen gas is flowed into the remote plasma source together with one or more additional gases such as helium (He). In certain embodiments, hydrogen source gas is provided in a carrier gas such as helium. As an example, hydrogen gas may be provided in a helium carrier at a concentration of about 1% to about 25% hydrogen or about 1% to about 10% hydrogen. Therefore, in some instances, H₂/He plasma is generated in the remote plasma source.

In an operation 650 of the process 600, the radicals of hydrogen are introduced into the reaction chamber and towards the substrate, where the radicals of hydrogen react with the one or more hydrocarbon precursors to deposit graphene on the metal surface of the substrate. The radicals of hydrogen are delivered into the reaction chamber under process conditions so that excited radicals transition to relaxed radicals without recombining. Pressure, fraction of carrier gas such as helium, geometry of gas ports of the showerhead, distance between the showerhead and the one or more gas outlets, and other process conditions are configured so that the hydrogen atoms encounter the substrate as radicals in a low energy state (e.g., ground state) without recombining. In some implementations, all or substantially all of the radicals of hydrogen in an environment adjacent to the substrate are radicals of hydrogen in the ground state. That way, the substrate is exposed to remote hydrogen plasma that minimizes surface growth damage.

Once generated, the radicals of hydrogen may be in an excited energy state. For example, hydrogen in an excited energy state can have an energy of at least 10.2 eV (first excited state). Excited radicals of hydrogen may cause surface growth damage of during graphene growth. In some implementations, when an excited hydrogen radical loses its energy, or relaxes, the excited hydrogen radical may become a substantially low energy state hydrogen radical or a ground state hydrogen radical. In some implementations, process conditions may be provided so that excited hydrogen radicals lose energy or relax to form substantially low energy state or ground state hydrogen radicals. For example, the remote plasma source or associated components may be designed so that a residence time of hydrogen radicals diffusing from the remote plasma source to the substrate is greater than the energetic relaxation time of an excited hydrogen radical. The energetic relaxation time for an excited hydrogen atom radical can be about equal to or less than about 1×10³ seconds. Other process conditions that are controlled so that excited hydrogen radicals lose energy to relax to form ground state hydrogen radicals include but are not limited to pressure, gas flow rates, size and geometry of relaxation zone, size and geometry of gas ports in the showerhead, and relative concentrations of hydrogen source gas to inert carrier gas.

An environment adjacent to the metal surface of the substrate may include the one or more hydrocarbon precursors. In addition, the environment adjacent to the metal surface of the substrate may include the radicals of hydrogen in the low energy state (e.g., ground state). The environment adjacent to the metal surface of the substrate comprises the metal surface as well as a space immediately above the exposed surface of the substrate. In effect, activation of the hydrocarbon precursors by radicals of hydrogen in the low energy state may occur on the metal surface or at a distance above the metal surface of the substrate. In some implementations, the distance above the metal surface of the substrate may be up to about 100 millimeters above the metal surface of the substrate. Typically, reaction conditions in the environment adjacent to the metal surface of the substrate are generally uniform across the entire metal surface of the substrate, though some variation may be permitted.

In some implementations, all, or substantially all, or a substantial fraction of the hydrogen atom radicals can be in the ground state, e.g., at least about 90% or 95% of the hydrogen atom radicals adjacent to the metal surface of the substrate are in the ground state. As used herein, radicals of hydrogen may also be referred to as “hydrogen radicals” and “hydrogen atom radicals.” A state in which a substantial fraction of hydrogen atom radicals are in the ground state can be achieved by various techniques. Some apparatuses, such as described in FIG. 7, are designed to achieve this state. The process conditions for achieving hydrogen atom radicals in the ground state may not have substantial amounts of ions, electrons, or radical species in high energy states such as states above the ground state. The presence of substantial amounts of ions or high energy radicals may cause surface growth damage on the substrate, resulting in low-quality graphene or disordered carbon growth. In some implementations, the concentration of ions in the environment adjacent to the metal surface of the substrate is no greater than about 10⁷/cm³. Hydrogen atom radicals in the ground state may provide sufficient energy for activating the one or more hydrocarbon precursors while providing mild conditions in the environment adjacent to the metal surface to limit surface growth damage.

The one or more hydrocarbon precursors are flowed into the reaction chamber downstream from the radicals of hydrogen. The radicals of hydrogen are generated in the remote plasma source located upstream from the one or more gas outlets for introducing the one or more hydrocarbon precursors. By the time the radicals of hydrogen reach the one or more hydrocarbon precursors, the radicals of hydrogen are in a low energy state or ground state upon mixing or interacting with the one or more hydrocarbon precursors.

Without being limited by any theory, one of the more kinetically favorable reaction mechanisms in the deposition reaction includes hydrogen abstraction, which results in activated hydrocarbon precursors. Without being limited by any theory, the hydrogen radicals in the low energy state or ground state may interact with the alkyne or alkene groups in the hydrocarbon molecule that results in the formation of activated alkanes (e.g., methane). In some instances, the hydrocarbon precursor breaks down into smaller-chain hydrocarbon molecules or radicals. Activated alkanes contain at least one carbon radical as an active site, and the active sites can react together to form carbon-to-carbon bonds in graphene. Bonding at the active sites and cross-linking can form a primary backbone or matrix in a resulting graphene film. The metal surface may act as a catalyst to promote reactions between activated hydrocarbon precursors.

The hydrocarbon precursors do not serve as passive spectators, but significantly contribute to the composition of the graphene. In some implementations, substantially all or a substantial fraction of the atoms in graphene are provided by the one or more hydrocarbon precursors, with small amounts of hydrogen or other element from the remote hydrogen plasma providing less than about 5 atomic percent or less than about 2 atomic percent of the film mass. In such cases, the low energy hydrogen atom radicals used to drive the deposition reaction do not substantially contribute to the mass of the deposited graphene.

The temperature in the environment adjacent to the metal surface of the substrate can be any suitable temperature facilitating the deposition reaction. In some implementations, the temperature in the environment adjacent to the metal surface of the substrate can be largely controlled by the temperature of a pedestal on which a substrate is supported during deposition of graphene. In some implementations, the operating temperature can be equal to or less than about 500° C., equal to or less than about 450° C., equal to or less than about 400° C., equal to or less than about 350° C., equal to or less than about 300° C., about 200° C. to about 400° C., about 250° C. to about 400° C., or about 200° C. to about 300° C. Such temperatures may be suitable for semiconductor applications. In some implementations, the temperature may depend on the metal of the metal surface on which the graphene is deposited. For example, copper may be able to sustain temperatures at 400° C. or below, whereas ruthenium may be able to sustain temperatures of 450° C. or below.

The pressure in the environment adjacent to the metal surface of the substrate can be any suitable pressure to promote graphene growth in the reaction chamber. In some embodiments, the pressure can be about 10 Torr or lower, or about 5 Torr or lower. For example, the pressure can be about 1 Torr to about 2 Torr.

Graphene may be selectively deposited on the metal surface from the reaction of radicals of hydrogen with the one or more hydrocarbon precursors provided downstream from the remote plasma source. Relatively mild reaction conditions provided by the radicals of hydrogen in a low energy state (e.g., ground state) activate the one or more hydrocarbon precursors to form carbon radicals. As such, the carbon radicals are formed outside of the remote plasma source in which plasma is generated. The amount of carbon radicals at the environment adjacent to the metal surface of the substrate may be controlled to limit having too many nucleation sites for graphene growth. Without being limited by any theory, an excess number of nucleation sites may correspond to an excess number of defects during graphene growth.

Graphene may be selectively deposited on a transition metal such as copper, ruthenium, nickel, molybdenum, cobalt, or combinations thereof. In some implementations, the metal surface includes copper. In some implementations, the graphene on the metal surface is relatively thin and may be on the order of a few monolayers thick. One monolayer of graphene may include one layer of sp2 hybridized carbon. In some embodiments, at least one monolayer of graphene is deposited. In some implementations, the thickness of the graphene is equal to or less than about nm, equal to or less than about 5 nm, equal to or less than about 3 nm, or equal to or less than about 1 nm. The thickness of the graphene may depend on the metal surface on which it is deposited on. For example, the thickness of the graphene may be less than about 1 nm when deposited on copper. The graphene may be a single layer graphene, bilayer graphene, or few layer graphene. The Raman spectrum of the graphene may be characterized by a D peak that is negligible in intensity and having a 2D peak that is equal to or greater than a G peak. It will be understood that the intensity of the D peak will be significantly smaller than the 2D peak and the G peak.

In some implementations, the process 600 may further include annealing the graphene on the metal surface of the substrate. Annealing the graphene may occur at elevated temperatures to remove defects from the graphene crystal structure. More specifically, annealing the graphene may occur at elevated temperatures greater than the deposition temperature of graphene. This ensures formation of high-quality graphene. In some implementations, the elevated temperatures may be equal to or greater than about 200° C., equal to or greater than about 250° C., equal to or greater than about 300° C., or equal to or greater than about 400° C. For example, if graphene were deposited at a temperature less than about 250° C., then annealing may occur at an elevated temperature greater than about 250° C.

Annealing the graphene may occur at a temperature range that is between the deposition temperature of graphene and a semiconductor processing temperature limit. The semiconductor processing temperature limit may be a temperature sensitive limit in which materials (e.g., metals) in the substrate would melt or otherwise be physically damaged. For example, the temperature sensitive limit of copper is about 400° C. and the temperature sensitive limit of ruthenium is about 450° C. The elevated temperature for annealing may depend on the metal in the semiconductor substrate and the temperature limits compatible with back-end-of-line semiconductor processing. Accordingly, annealing may take place at a temperature greater than the deposition temperature of graphene but at a temperature that does not exceed the semiconductor processing temperature limit. In some implementations, the temperature range for annealing the graphene is about 200° C. to about 450° C., about 200° C. to about 400° C., about 250° C. to about 400° C., or about 300° C. to about 350° C.

Annealing the graphene may result in significant improvement in the quality of graphene with reduced defects, where the D peak is decreased, the ratio between the 2D peak and the G peak is increased, and/or the ratio between the G peak and the D peak is increased. As discussed earlier, decreasing the D peak is indicative of removal of defects in the crystal structure of graphene. Increasing the ratio between the 2D peak and the G peak is indicative of the presence of single layer graphene, bilayer graphene, or few layer graphene as opposed to disordered or amorphous carbon. The higher the ratio, the higher the crystallinity of the film. For example, annealing the graphene may increase the ratio between the 2D peak and the G peak from about 1:1 to about 2:1. Furthermore, increasing the ratio between the G peak and the D peak is indicative of increased grain size. Annealing can remove any adsorbates or defects that disrupt the planar structure of graphene while increasing grain size, thereby improving film quality. In some implementations, annealing the graphene occurs in air or inert gas atmosphere, where the inert gas atmosphere includes an inert gas such as argon (Ar), helium (He), nitrogen (N₂), or combinations thereof. In some implementations, annealing can take place for a duration that is equal to or less than about 30 minutes, equal to or less than about 20 minutes, equal to or less than about 10 minutes, or equal to or less than about 5 minutes.

Graphene films ordinarily do not undergo annealing operations. This is because graphene is typically deposited at high temperatures, e.g., greater than about 400° C. However, when graphene is deposited at low temperatures, e.g., about 200° C. to about 300° C., annealing may be an important step that improves graphene film quality without exceeding a temperature sensitive limit in semiconductor processing. In other words, annealing occurs within the back-end-of-line thermal budget constraints. Therefore, annealing may be an important step in integrating graphene in semiconductor processing applications. In some implementations, annealing may occur after graphene deposition but before and/or after deposition of an etch stop, diffusion barrier, or hermetic barrier.

Graphene may lower the effective resistivity of metal lines and limit electromigration. With low temperature deposition of graphene, graphene may be integrated in a process flow for manufacturing semiconductor devices, such as in back-end-of-line (BEOL) semiconductor processing. BEOL semiconductor processing may involve providing electrical interconnection between metallization layers with one or more conductive vias. During BEOL semiconductor processing, graphene may be deposited on the metallization layers or metal lines.

### Apparatus

Certain disclosed embodiments may be performed in any suitable processing chamber, the chamber including a heatable pedestal, showerhead, reactant delivery system, and inlets for delivering one or more gases to the processing chamber. The chamber may be a single-wafer chamber or a station within a multi-station chamber or a standalone process station. Hardware parameters of the processing chamber may be adjusted programmatically by one or more computer controllers. The reactant delivery system may include an optional mixing vessel and multiple inlet valves that control introduction of process gases to the mixing vessel and/or to the showerhead and/or to the processing chamber. In some embodiments, a vaporization point may be used to form vapor phase process gases.

One aspect of the disclosure is an apparatus configured to accomplish the graphene deposition methods described herein. A suitable apparatus includes hardware for accomplishing the process operations and a system controller having instructions for controlling process operations in accordance with the present disclosure. In some implementations, the apparatus for performing the aforementioned process operations can include a remote plasma source. A remote plasma source provides mild reaction conditions compared to a direct plasma.

FIG. 7 illustrates a schematic diagram of an example plasma processing apparatus with a remote plasma source according to some implementations. The plasma processing apparatus 700 includes the remote plasma source 702 separated from a reaction chamber 704. The remote plasma source 702 is fluidly coupled with the reaction chamber 704 via a showerhead 706, which may also be referred to as a multiport gas distributor. Radical species are generated in the remote plasma source 702 and supplied to the reaction chamber 704. One or more hydrocarbon precursors are supplied to the reaction chamber 704 downstream from the remote plasma source 702 and downstream from the showerhead 706. The one or more hydrocarbon precursors react with the radical species in a chemical vapor deposition zone 708 of the reaction chamber 704 to deposit a graphene film on a front surface of a substrate 712. The chemical vapor deposition zone 708 includes an environment adjacent to the front surface of the substrate 712, where the front surface of the substrate 712 faces the remote plasma source 702.

The substrate 712 is supported on a substrate support or pedestal 714. The pedestal 714 may move within the reaction chamber 704 to position the substrate 712 within the chemical vapor deposition zone 708. In the embodiment shown in FIG. 7, pedestal 714 is shown having elevated the substrate 712 within the chemical vapor deposition zone 708. The pedestal 714 may also adjust the temperature of the substrate 712 in some embodiments, which can provide some selective control over thermally activated surface reactions on the substrate 712.

FIG. 7 shows a coil 718 arranged around the remote plasma source 702, where the remote plasma source 702 includes an outer wall (e.g., quartz dome). The coil 718 is electrically coupled to a plasma generator controller 722, which may be used to form and sustain plasma within a plasma region 784 via inductively coupled plasma generation. In some implementations, the plasma generator controller 722 may include a power supply for supplying power to the coil 718, where the power can be in a range about 1 to about 6 kilowatts (kW) during plasma generation. In some implementations, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 784, radical species may continuously be generated using plasma excitation during film deposition. In some implementations, hydrogen radicals are generated under approximately steady-state conditions during steady-state film deposition, though transients may occur at the beginning and end of film deposition.

A supply of hydrogen radicals may be continuously generated within the plasma region 784 while hydrogen gas or other source gas is being supplied to the remote plasma source 702. Excited hydrogen radicals may be generated in the remote plasma source 702. If not re-excited or re-supplied with energy, or re-combined with other radicals, the excited hydrogen radicals lose their energy, or relax. Thus, excited hydrogen radicals may relax to form hydrogen radicals in a substantially low energy state or ground state. The hydrogen radicals in the substantially low energy state or ground state.

The hydrogen gas (H₂) or other source gas may be diluted with one or more additional gases. These one or more additional gases may be supplied to the remote plasma source 702. In some implementations, the hydrogen gas or other source gas is mixed with one or more additional gases to form a gas mixture, where the one or more additional gases can include a carrier gas. Non-limiting examples of additional gases can include helium (He), neon (Ne), argon (Ar), krypton (Kr), xenon (Xe), and nitrogen (N₂). The one or more additional gases may support or stabilize steady-state plasma conditions within the remote plasma source 702 or aid in transient plasma ignition or extinction processes. In some implementations, diluting hydrogen gas or other source gas with helium, for example, may permit higher total pressures without concomitant plasma breakdown. Put another way, a dilute gas mixture of hydrogen gas and helium may permit higher total gas pressure without increasing plasma power to the remote plasma source 702. In certain embodiments, hydrogen gas is provided in a carrier such as helium. As an example, hydrogen gas may be provided in a helium carrier at a concentration of about 1% to about 25% hydrogen or about 1% to about 10% hydrogen.

As shown in FIG. 7, a source gas supply 726 is fluidly coupled with the remote plasma source 702 for supplying the hydrogen gas or source gas or for deposition of the inhibitor layer on a barrier layer, for supplying silicon-containing gases and/or oxygen-containing gases. In some embodiments, deposition of the inhibitor layer is performed in a separate reaction chamber from the deposition of the graphene layer. In some embodiments, deposition of the inhibitor layer is performed in a reaction chamber such as reaction chamber 704, but source gas supply 726 is used to supply inhibitor layer deposition gases, and remote plasma source 702 is optional. In addition, an additional gas supply 728 is fluidly coupled with the remote plasma source 702 for supplying the one or more additional gases. The one or more additional gases may also include a co-reactant gas. While the embodiment in FIG. 7 depicts the gas mixture of the source gas and the one or more additional gases being introduced through separate gas outlets, it will be understood that the gas mixture may be introduced directly into the remote plasma source 702. That is, a pre-mixed dilute gas mixture may be supplied to the remote plasma source 702 through a single gas outlet.

Gases, such as excited hydrogen and helium radicals and relaxed gases/radicals, flow out of the remote plasma source 702 and into the reaction chamber 704 via the showerhead 706. Gases within the showerhead 706 and within the reaction chamber 704 are generally not subject to continued plasma excitation therein. In some implementations, the showerhead 706 includes an ion filter and/or a photon filter. Filtering ions and/or photons may reduce substrate damage, undesirable re-excitation of molecules, and/or selective breakdown or decomposition of hydrocarbon precursors within the reaction chamber 704. Showerhead 706 may have a plurality of gas ports 744 to diffuse the flow of gases into the reaction chamber 704. In some implementations, the plurality of gas ports 744 may be mutually spaced apart. In some implementations, the plurality of gas ports 744 may be arranged as an array of regularly spaced apart channels or through-holes extending through a plate separating the remote plasma source 702 and the reaction chamber 704. The plurality of gas ports 744 may smoothly disperse and diffuse exiting radicals from the remote plasma source 702 into the reaction chamber 704.

Typical remote plasma sources are far removed from reaction vessels. Consequently, radical extinction and recombination, e.g., via wall collision events, may reduce active species substantially. In contrast, in some implementations, dimensions for the plurality of gas ports 744 may be configured in view of the mean free path or gas flow residence time under typical processing conditions to aid the free passage of radicals into the reaction chamber 704. In some implementations, openings for the plurality of gas ports 744 may occupy about 5% to about 20% of an exposed surface area of the showerhead 706. In some implementations, the plurality of gas ports 744 may each have an axial length to diameter ratio of about 3:1 to about 10:1 or about 6:1 to about 8:1. Such aspect ratios may reduce wall-collision frequency for radical species passing through the plurality of gas ports 744 while providing sufficient time for a majority of excited state radical species to relax to ground state radical species. In some implementations, dimensions of the plurality of gas ports 744 may be configured so that the residence time of gases passing through the showerhead 706 is greater than the typical energetic relaxation time of an excited state radical species. Excited state radical species for hydrogen source gas may be denoted by ·H* in FIG. 7 and ground state radical species for hydrogen source gas may be denoted by ·H in FIG. 7.

In some implementations, excited state radical species exiting the plurality of gas ports 744 may flow into a relaxation zone 738 contained within an interior of the reaction chamber 704. The relaxation zone 738 is positioned upstream of the chemical vapor deposition zone 708 but downstream of the showerhead 706. Substantially all or at least 90% of the excited state radical species exiting the showerhead 706 will transition into relaxed state radical species in the relaxation zone 738. Almost all of the excited state radical species (e.g., excited hydrogen radicals) entering the relaxation zone 738 become de-excited or transition into a relaxed state radical species (e.g., ground state hydrogen radicals) before exiting the relaxation zone 738. In some implementations, process conditions or a geometry of the relaxation zone 738 may be configured so that the residence time of radical species flowing through the relaxation zone 738, e.g., a time determined by mean free path and mean molecular velocity, results in relaxed state radical species flowing out of the relaxation zone 738.

With the delivery of radical species to the relaxation zone 738 from the showerhead 706, one or more hydrocarbon precursors may be introduced into the chemical vapor deposition zone 708. The one or more hydrocarbon precursors may be introduced via a gas distributor or gas outlet 742, where the gas outlet 742 may be fluidly coupled with a precursor supply source 740. The relaxation zone 738 may be contained within a space between the showerhead 706 and the gas outlet 742. The gas outlet 742 may include mutually spaced apart openings so that the flow of the one or more hydrocarbon precursors may be introduced in a direction parallel with gas mixture flowing from the relaxation zone 738. The gas outlet 742 may be located downstream from the showerhead 706 and the relaxation zone 738. The gas outlet 742 may be located upstream from the chemical vapor deposition zone 708 and the substrate 712. The chemical vapor deposition zone 708 is located within the interior of the reaction chamber 704 and between the gas outlet 742 and the substrate 712.

Substantially all of the flow of the one or more hydrocarbon precursors may be prevented from mixing with excited state radical species adjacent to the showerhead 706. Relaxed or ground state radical species mix in a region adjacent to the substrate 712 with the one or more hydrocarbon precursors. The chemical vapor deposition zone 708 includes the region adjacent to the substrate 712 where the relaxed or ground state radical species mix with the one or more hydrocarbon precursors. The relaxed or ground state radical species mix with the one or more hydrocarbon precursors in the gas phase during CVD formation of graphene.

In some implementations, a co-reactant may be introduced from the showerhead 706 and flowed along with the radical species generated in the remote plasma source 702 and into the reaction chamber 704. This may include radicals and/or ions of a co-reactant gas provided in the remote plasma source 702. The co-reactant may be supplied from the additional gas supply 728. In some implementations, the co-reactant may include a nitrogen-containing agent such as nitrogen gas (N₂). For example, radicals and/or ions of nitrogen may be generated and flowed with the radical species of hydrogen during pretreatment of a metal surface of the substrate 712.

The gas outlet 742 may be separated from the showerhead 706 by a sufficient distance to prevent back diffusion or back streaming of the one or more hydrocarbon precursors. This can afford sufficient time for radical species of hydrogen to transition from an excited state to a relaxed state (e.g., ground state). In some implementations, the gas outlet 742 may be separated from the plurality of gas ports 744 by a distance about 0.5 inches to about 5 inches, or about 1.5 inches to about 4.5 inches, or about 1.5 inches to about 3 inches.

Process gases may be removed from the reaction chamber 704 via an outlet 748 that is fluidly coupled to a pump (not shown). Thus, excess hydrocarbon precursors, co-reactants, radical species, and diluent and displacement or purge gases may be removed from the reaction chamber 704. In some implementations, a controller 750 is in operative communication with the plasma processing apparatus 700. In some implementations, the controller 750 includes a processor system 752 (e.g., microprocessor) configured to execute instructions held in a data system 754 (e.g., memory). In some implementations, the controller 750 may be in communication with the plasma generator controller 722 to control plasma parameters and/or conditions. In some implementations, the controller 750 may be in communication with the pedestal 714 to control pedestal elevation and temperature. In some implementations, the controller 750 may control other processing conditions, such as RF power settings, frequency settings, duty cycles, pulse times, pressure within the reaction chamber 704, pressure within the remote plasma source 702, gas flow rates from the source gas supply 726 and the additional gas supply 728, gas flow rates from the precursor supply source 740 and other sources, temperature of the pedestal 714, and temperature of the reaction chamber 704, among others.

The controller 750 may contain instructions for controlling process conditions for the operation of the plasma processing apparatus 700. The controller 750 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 750 or they may be provided over a network.

In certain embodiments, the controller 750 controls all or most activities of the plasma processing apparatus 700 described herein. For example, the controller 750 may control all or most activities of the plasma processing apparatus 700 associated with depositing graphene and, optionally, other operations in a fabrication flow that includes the graphene. The controller 750 may execute system control software including sets of instructions for controlling the timing, gas composition, gas flow rates, chamber pressure, chamber temperature, RF power levels, substrate position, and/or other parameters. Other computer programs, scripts, or routines stored on memory devices associated with the controller 750 may be employed in some embodiments. To provide relatively mild reactive conditions at the environment adjacent to the substrate 712, parameters such as the RF power levels, gas flow rates to the plasma region 784, gas flow rates to the chemical vapor deposition zone 708, and timing of the plasma ignition can be adjusted and maintained by controller 750. Additionally, adjusting the substrate position may further reduce the presence of high-energy radical species at the environment adjacent to the substrate 712. In a multi-station reactor, the controller 750 may comprise different or identical instructions for different apparatus stations, thus allowing the apparatus stations to operate either independently or synchronously.

In some embodiments, the controller 750 may include instructions for performing operations such as flowing one or more hydrocarbon precursors through the gas outlet 742 into the reaction chamber 704, providing a source gas into the remote plasma source 702, generating one or more radical species of the source gas in the remote plasma source 702 upstream of the one or more hydrocarbon precursors, introducing the one or more radical species from the remote plasma source 702 into the reaction chamber 704 to react with the one or more hydrocarbon precursors to deposit a graphene on a metal surface of the substrate 712. The one or more radical species in the reaction chamber 704 in an environment adjacent to the substrate 712 may be hydrogen radicals in a ground state. In some implementations, the controller 750 may include instructions for treating the metal surface of the substrate 712 prior to depositing graphene. In some implementations, the controller 750 may include instructions for maintaining a temperature of the substrate 712 equal to or less than about 400° C., or about 200° C. to about 400° C. In some implementations, each of the one or more hydrocarbon precursors includes an alkene or alkyne group.

In some embodiments, the plasma processing apparatus 700 may include a user interface associated with controller 750. The user interface may include a display screen, graphical software displays of the plasma processing apparatus 700 and/or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the controller. The signals for controlling the process are output on the analog and digital output connections of the processing system.

In general, the methods described herein can be performed on systems including semiconductor processing equipment such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. In general, the electronics are referred to as the controller 750, which may control various components or subparts of the system or systems. The controller 750, depending on the processing requirements and/or the type of system, may be programmed to control any of the processes disclosed herein, including the delivery of processing gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 750 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials (e.g., silicon carbide), surfaces, circuits, and/or dies of a wafer.

The controller 750, in some implementations, may be a part of or coupled to a computer that is integrated with, coupled to the system, otherwise networked to the system, or a combination thereof. For example, the controller 750 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 750 receives instructions in the form of data, which specify parameters for each of the processing steps to be performed during one or more operations. It should be understood that the parameters may be specific to the type of process to be performed and the type of tool that the controller 750 is configured to interface with or control. Thus as described above, the controller 750 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In addition to graphene deposition described herein, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller 750 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

FIG. 8 depicts a schematic illustration of an embodiment of an atomic layer deposition (ALD) process station 800 having a process chamber body 802. A plurality of ALD process stations 800 may be included in a common low pressure process tool environment. In some embodiments, one or more hardware parameters of ALD process station 800 including those discussed in detail below may be adjusted programmatically by one or more computer controllers 850.

ALD process station 800 fluidly communicates with reactant delivery system 801a for delivering process gases to a distribution showerhead 806. Reactant delivery system 801a includes a mixing vessel 804 for blending and/or conditioning process gases, such as a blocking reagent gas, metal precursor gas, or oxygen-containing gas for delivery to showerhead 806. One or more mixing vessel inlet valves 820 may control introduction of process gases to mixing vessel 809.

As an example, the embodiment of FIG. 8 includes a vaporization point 803 for vaporizing liquid reactant to be supplied to the mixing vessel 804. In some embodiments, vaporization point 803 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput Thus, in some embodiments, delivery piping downstream of vaporization point 803 may be heat traced. In some examples, mixing vessel 804 may also be heat traced. In one non-limiting example, piping downstream of vaporization point 803 has an increasing temperature profile extending from approximately 100° C. to approximately 150° C. at mixing vessel 804.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 803. In one scenario, a liquid injector may be mounted directly to mixing vessel 804. In another scenario, a liquid injector may be mounted directly to showerhead 806.

In some embodiments, a liquid flow controller (LFC) upstream of vaporization point 803 may be provided for controlling a mass flow of liquid for vaporization and delivery to process station 800. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 806 distributes process gases toward substrate 812. In the embodiment shown in FIG. 8, the substrate 812 is located beneath showerhead 806 and is shown resting on a pedestal 808. Showerhead 806 may have any suitable shape, and may have any suitable number and arrangement of ports for distributing process gases to substrate 812.

In some embodiments, pedestal 808 may be raised or lowered to expose substrate 812 to a volume between the substrate 812 and the showerhead 806. It will be appreciated that, in some embodiments, pedestal height may be adjusted programmatically by a suitable computer controller 850. At the conclusion of the process phase, pedestal 808 may be lowered during another substrate transfer phase to allow removal of substrate 812 from pedestal 808.

In some embodiments, pedestal 808 may be temperature controlled via heater 810. In some embodiments, the pedestal 808 may be heated to a temperature of at least about 25° C., or about 25° C. to about 400° C. In various embodiments, process station 800 is used without igniting a plasma.

Further, in some embodiments, pressure control for process station 800 may be provided by butterfly valve 818. As shown in the embodiment of FIG. 8, butterfly valve 818 throttles a vacuum provided by a downstream vacuum pump (not shown). However, in some embodiments, pressure control of process station 800 may also be adjusted by varying a flow rate of one or more gases introduced to the process station 800.

In some embodiments, a position of showerhead 806 may be adjusted relative to pedestal 808 to vary a volume between the substrate 812 and the showerhead 806. Further, it will be appreciated that a vertical position of pedestal 808 and/or showerhead 806 may be varied by any suitable mechanism within the scope of the present disclosure. In some embodiments, pedestal 808 may include a rotational axis for rotating an orientation of substrate 812. It will be appreciated that, in some embodiments, one or more of these example adjustments may be performed programmatically by one or more suitable computer controllers 850.

In plasma-based processes, adjusting a height of pedestal 808 may allow a plasma density to be varied during plasma activation cycles in the process in embodiments where a plasma is ignited. In some embodiments where plasma may be used, showerhead 806 and pedestal 808 electrically communicate with a radio frequency (RF) power supply (not shown) and matching network (not shown) for powering a plasma. In some embodiments, the plasma energy may be controlled by controlling one or more of a process station pressure, a gas concentration, an RF source power, an RF source frequency, and a plasma power pulse timing. For example, the RF power supply and the matching network may be operated at any suitable power to form a plasma having a desired composition of radical species. Examples of suitable powers are about 150 W to about 6000 W. Plasma may be used to deposit and/or to remove an inhibitor layer. The RF power supply may provide RF power of any suitable frequency. In some embodiments, The RF power supply may be configured to control high- and low-frequency RF power sources independently of one another. Example low-frequency RF frequencies may include, but are not limited to, frequencies about 0 kHz to about 500 kHz. Example high-frequency RF frequencies may include, but are not limited to, frequencies about 1.8 MHz to about 2.45 GHz, or greater than about 13.56 MHz, or greater than 27 MHz, or greater than 40 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 850 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inhibitor layer deposition precursor, instructions for setting a flow rate of a carrier gas (such as argon), and time delay instructions for the first recipe phase. A second recipe phase may include instructions for modulating or stopping a flow rate of an inert and/or a reactant gas, and instructions for modulating a flow rate of a carrier or purge gas and time delay instructions for the second recipe phase. A third, subsequent recipe phase may include instructions for modulating a flow rate of an graphene layer reactant gas, instructions for modulating the flow rate of a carrier or purge gas, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the disclosed embodiments. In some embodiments, the controller 850 may include any of the features described above with respect to controller 750 of FIG. 7.

### CONCLUSION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for forming a dual damascene structure on a semiconductor substrate, the method comprising:
providing the semiconductor substrate comprising a first dielectric layer and a copper interconnect in the first dielectric layer, the copper interconnect having an exposed metal surface, wherein the exposed metal surface comprises copper; and
selectively depositing a carbon layer on the exposed metal surface.

2. The method of claim 1, wherein selectively depositing the carbon layer on the exposed metal surface comprises:
flowing one or more hydrocarbon precursors into a reaction chamber and towards the semiconductor substrate;
generating, from a hydrogen source gas, radicals of hydrogen in a remote plasma source; and
introducing the radicals of hydrogen into the reaction chamber and towards the semiconductor substrate,
wherein the radicals of hydrogen react with the one or more hydrocarbon precursors to deposit the carbon layer on the exposed metal surface.

3. The method of claim 1, wherein the carbon layer comprises carbon bonded in a hexagonal lattice.

4. The method of claim 1, wherein the carbon layer is selectively deposited at a temperature of less than about 400° C.

5. The method of claim 1, further comprising treating the carbon layer with a non-direct plasma.

6. The method of claim 5, wherein the non-direct plasma comprises radicals selected from the group consisting of OH* radicals, O* radicals, H* radicals, radicals of ammonia, radicals of nitrogen, and combinations thereof.

7. The method of claim 1, further comprising, after selectively depositing the carbon layer on the exposed metal surface, depositing a hermetic barrier over the carbon layer.

8. The method of claim 7, further comprising depositing a second dielectric material over the hermetic barrier.

9. The method of claim 8, wherein the carbon layer inhibits deposition of the second dielectric material on the carbon layer when the second dielectric material is deposited on the first dielectric layer.

10. The method of claim 8, wherein the second dielectric material comprises a metal oxide.

11. The method of claim 10, wherein the metal oxide comprises aluminum oxide, hafnium oxide, zirconium oxide, yttrium oxide, zinc oxide, titanium oxide, or combinations thereof.

12. The method of claim 1, wherein the carbon layer is deposited to a thickness of less than about 3 monolayers.

13. The method of claim 1, wherein the first dielectric layer comprises a low-k dielectric material.

14. A semiconductor device comprising:
a first dielectric layer having a via;
a liner layer conformally lining sidewalls of the via;
a copper material formed over the liner layer in the via, the copper material having an exposed cobalt-free copper surface planar with a planar surface of the first dielectric layer;
a carbon cap selectively formed directly on the exposed cobalt-free copper surface relative to the first dielectric layer and treated by exposure to plasma;
a hermetic barrier over the carbon cap; and
a second dielectric layer formed over the hermetic barrier.

15. The semiconductor device of claim 14, wherein the second dielectric layer comprises a metal oxide.

16. The semiconductor device of claim 15, wherein the metal oxide comprises aluminum oxide, hafnium oxide, zirconium oxide, yttrium oxide, zinc oxide, titanium oxide, or combinations thereof.

17. The semiconductor device of claim 16, wherein the carbon cap has a thickness of less than about 3 monolayers.

18. The semiconductor device of claim 17, wherein the carbon cap comprises sp2 hybridized carbon.
